(19) United States
(12) Patent Application Publication
(10) Pub. No.: US 2025/0091478 A1
(43) Pub. Date: Mar. 20, 2025

(54) METHOD FOR DETERMINING THE PERFORMANCE CAPABILITY OF ELECTRICAL VEHICLE ENERGY STORES

(71) Applicant: VOLYTICA DIAGNOSTICS GMBH, Dresden (DE)

(72) Inventors: Claudius JEHLE, München (DE); Sebastian STOLL, Dresden (DE); Lutz MORAWIETZ, Dresden (DE)

(21) Appl. No.: 18/290,712

(22) PCT Filed: Jul. 20, 2022
(86) PCT No.: PCT/EP2022/070392

§ 371 Date: Jan. 19, 2024

(30) Foreign Application Priority Data
Jul. 20, 2021 (DE) 10 2021 118 781.8

(51) Int. Cl. B60L 58/16; B60L 53/30; B60L 53/65; B60L 53/66; B60L 53/68; B60L 58/12

(52) U.S. Cl. CPC B60L 58/16; B60L 53/305; B60L 53/65; B60L 53/66; B60L 53/68; B60L 58/12; B60L 2240/545; B60L 2240/547; B60L 2240/549

(57) ABSTRACT

The present invention relates to the field of electric vehicles, in particular to a method for determining the performance of an electric vehicle energy storage system. A method is provided that enables the performance of electrical energy storage devices to be determined from outside a vehicle without access to its internal communication and electronic systems. The method can be implemented with a charging device. The performance is related to the resistance and/or the energy absorption capacity of the electrical energy storage device. The resistance is determined via a variable charging or discharging current, whereby the variable current has a defined increase or decrease in a defined period of time and reaches a predetermined current intensity. The capacity is calculated either via the measured resistance using known relationships or relationships to be determined, e.g. using statistics or previous measurement, or via the determination by measuring duration, charging current and, advantageously, information about the voltage.

### TECHNICAL AREA

The present invention relates to the field of electric vehicles, in particular to a method for determining the performance of an electric vehicle energy storage system.

### STATE OF THE ART

In the field of electric vehicles, performance, sometimes referred to as SoH (State of Health), is an important parameter or set of parameters of the vehicle battery and is used as an indicator of the battery's state of health. State of health (SoH or SOH) is often used as a parameter for batteries that describes their performance in the context of their ageing. The skilled person understands this to mean at least one parameter that describes a statement about the ability of the storage device to fulfill its designated requirement. It is often understood to mean its ability to store and release a certain amount of energy or charge (also capacity or maximum capacity). It is also often understood as the speed at which this can be released or absorbed (performance, power), which is related to its impedance, often simplified as resistance. The focus here is on the state of the energy storage device. Like all other devices equipped with a rechargeable energy storage unit, the performance of this energy storage unit is also reduced in electric cars. Many manufacturers offer SoH guarantees for their e-cars, which include the loss of battery capacity. In the state of the art, the state of health of the battery is recorded by a battery management system (BMS) located inside the vehicle using a large amount of factory test data from the battery via an online test.

In electric vehicles, the electrical energy storage system accounts for a significant proportion of the monetary value. As an energy storage system ages, the resistance often increases or the impedance changes, which reduces its performance. The capacity and therefore the range also decreases. In an exemplary scenario of a used car sale, it is therefore of interest to assess the performance of the electric energy storage system as accurately as possible. The customer/vehicle owner is particularly interested in the remaining range that can be achieved with a battery or the energy storage system, which can be an important aspect of performance.

Patent specification EP 2 306 214 A1 discloses a method whereby the DC impedance is measured and this impedance is compared with a reference resistor. The resistance is measured both when charging and discharging the battery. For the measurement method, the battery is warmed up or cooled down to 35° C. when charging the battery in order to obtain optimum charging conditions and minimal delay in the charging process due to the measurement. This system uses a dedicated communication bus between the charger, the battery management system and the assessment system. However, the measurement method thus requires that measured values from the vehicle, in particular from the vehicle's CPU or BMS, must be consulted, which is not generally possible without the existence of a known, suitable, disclosed interface for an independent third party. The procedure is therefore only possible for the vehicle manufacturer or its contractors, but not for independent parties.

DE 10 2017 125 274 B3 discloses a method for recording the health status of a battery. For this purpose, a system consisting of a vehicle, its energy storage system, a charging device and a cloud server is used. This system records the battery data such as temperature, current, voltage, SOC (State Of Charge), manufacturer, type, past error codes and past exception codes while the battery is in the charging state and transmits the recorded charging data to the cloud server. The cloud server only determines the health status of the battery after the battery has finished charging based on all the stored charging data using an algorithmic model. Although this algorithmic model can be designed to be adaptive and updated after each charging process, this process is very time-consuming, as the state of health of the energy storage system can only be determined after charging is complete, i.e. after the storage system has been completely filled (which can take several hours), and only as a function of all the stored charging data.

WO2020045059A1 discloses a diagnostic apparatus comprising: a detection part that detects first charging information including a first detected value detected by an external charger while charging a battery installed in a vehicle, and second charging information including a second detected value detected by the vehicle; and a deterioration estimation part that estimates a degree of deterioration indicating deterioration of the battery based on the first charging information and the second charging information. However, the method and the disclosed apparatus are limited in accuracy, thereby providing only an insufficiently accurate estimation.

Patent EP 2 065 718 B1 defines the deterioration of the battery as the change in charging efficiency. The charging efficiency is calculated by measuring the amount of electricity supplied to the vehicle by the charging station and the energy actually stored in the vehicle's energy storage system. The calculated charging efficiency is stored locally in a degradation assessment system, which is part of the charging station. The power transmission cable is also used for communication between the vehicle energy storage system and the assessment system. Another disadvantage here is that the charging efficiency of the energy storage system can only be calculated if the amount of energy actually stored in the vehicle's energy storage system is known, which means that measured values from the vehicle's control units or CPUs must also be used here. The procedure is therefore only possible for the vehicle manufacturer or its contractors, not for independent parties.

Patent WO 2011 135813 A1 discloses a condition management system for an energy storage device, which comprises a charger that records the electrical properties during the charging of an energy storage device and compares these with the parameters stored in a data memory for the same energy storage device and determines the condition of this energy storage device from this. The measured data recorded are charging current, charging voltage and ambient temperature of the charger and are compared with historical data stored in a measurement information storage unit of this energy storage device. The deterioration of the battery is determined from the comparison. The battery communicates with the charger and the server. Past charging data is stored on the server. The server also contains an analytics module that determines the deterioration of the battery.

This procedure is therefore also only possible for the vehicle manufacturer or its contractors, not for independent parties.

As a result, it is not yet possible for independent third parties to independently assess the performance of electrical energy storage systems. Only vehicle and battery manufacturers with access rights to the internal control units, e.g. CPUs, which communicate with the BMS are in a position to do so. An independent third party would be, for example, the vehicle owner, a used car dealer or a vehicle workshop. If there is a possibility for independent third parties, this is always adapted to a vehicle or a specific vehicle type or energy storage system, and this possibility cannot be transferred to other circumstances. It is not possible to compare the performance of different electrical energy storage systems. Rather, the above-mentioned solutions require the unproblematic, both technical and legal, availability of the signals to be measured within a vehicle or an electrical energy storage device.

As independent third parties have so far been denied access to internal vehicle systems such as the CPU, particularly by the vehicle manufacturers, the data processed there, especially the BMS data, cannot be accessed by independent third parties, or only to a limited extent.

Furthermore, the currently known methods for determining the performance of a battery concentrate on the time-consuming determination of the charge content (complete full/discharge) within a period of time.

The state of the art therefore currently offers no possibility of a quick and independent determination of the performance of a battery by an independent third party without having to access the internal vehicle systems.

None of the solutions known from the state of the art take into account the idle time of the vehicles, whereby the energy storage units were virtually not used. Furthermore, none of the solutions described in the aforementioned patent specifications take into account the environmental data (e.g. temperature, humidity) of the energy storage unit. However, the inventors of this solution approach have discovered that this data is also of interest, as it allows conclusions to be drawn about the state, in particular the thermal, electrochemical, chemical and thermodynamic equilibrium, of the energy storage device, which is helpful for determining the performance or values associated with it more precisely and/or more quickly (e.g. to compensate for parasitic effects).

### Object

It is therefore the object of the present invention to provide a method with which the performance of an electric vehicle energy storage system can be reliably and precisely assessed in a short period of time without having to rely on detailed information from the vehicle that is not accessible to an independent third party.

It is particularly important that the method can be used flexibly, for a wide variety of vehicle types and is accessible to independent third parties without compromising the accuracy, reliability and precision of the performance determination obtained.

### Solution

The present invention provides a method that enables the performance of electrical energy storage devices to be determined from outside a vehicle without accessing its internal communication and electronic systems.

The present tasks are solved by a method for determining the performance of electric vehicle energy storage systems, which comprises the following steps:
a) Provision of a vehicle energy storage unit on an intermediate circuit,
b) Providing a charging device that can be detached from the vehicle energy storage system or the intermediate circuit,
c) Provision of at least two current-carrying power channels, preferably directly from the charging device to the vehicle energy storage system or the intermediate circuit,
d) Determining at least one current, in particular at least one amperage, of the vehicle energy storage system,
e) Determining at least one voltage of the vehicle energy storage system,
f) Determining at least one resistance of the vehicle energy storage system, and
g) Determination of further physical variables as measured values,
characterized in that
a temporally variable current increase or current drop is used to determine the performance, in particular the resistance, of the vehicle energy storage system,
whereby the current and voltage are determined outside the vehicle, preferably inside the charging device,
whereby influences of components other than the energy storage device on the intermediate circuit and/or components between the charging device and the energy storage device are factored out to determine the performance of the energy storage device, in particular parasitic effects,
whereby at least one external physical variable and already known information about the energy storage device or already known information about energy storage devices comparable to the energy storage device are used to eliminate those influences.

The information, which can be accessed independently from the outside, is processed professionally in such a way that any measured or co-determined effects that cannot be attributed to the performance of the storage system—such as effects from the intermediate circuit and/or ambient conditions (generally “parasitic effects”)—are isolated and largely removed from the calculation. This procedure creates a flexible and at the same time particularly precise determination of performance. In particular, the performance determinations are easily comparable and free of parasitic effects, especially in the respective vehicle. The latter results in increased precision and accuracy with regard to the technically really interesting physical variable(s).

The charging device is preferably connected to the vehicle energy storage system via at least two current-carrying power channels from the charging device to the vehicle energy storage system or the intermediate circuit within the vehicle on which the energy storage system is located, so that these are preferably connected directly to each other. The term “direct” in this context means that the charging device is directly electrically coupled to the vehicle energy storage system and/or the DC link, i.e. not via active power electronics such as an inverter (“DC coupling”).

Preferably, the temporary determination of the charging data of the vehicle energy storage system and/or the intermediate circuit is carried out by the charging device within a time interval Δt_{E} during the period of the charging and/or discharging process Δt_{A}, where Δt_{E}<Δt_{A}. This has the advantage that the method for determining the performance of the energy storage device can be carried out much faster, since, in contrast to the prior art, it is not necessary to wait until the energy storage device is fully charged, i.e. the energy storage device (in this case, for example, the battery or the accumulator) is in the charging state, because, for example, all charging data of the relevant vehicle or the energy storage device must be determined. According to the invention, this is realized by the fact that, within the method, a time-variable current increase or current drop is used to determine the performance, in particular the resistance of the vehicle energy storage system, and already known information about the energy storage system or already known information about energy storage systems comparable to the energy storage system is used.

A charging device for electric vehicle energy storage systems is required to solve the problem. The method can be implemented in it. The performance is related to the resistance and/or the energy absorption capacity of the electrical energy storage device. The resistance is determined via a variable charging or discharging current, whereby the variable current has a defined increase or decrease in a defined period of time and reaches a predetermined current intensity. It is irrelevant whether charging or discharging is involved.

In particular, a resistance or an impedance, especially a resistance or an impedance of the energy storage device, can also be determined via measured values that result immediately during and after a strong reduction of the current (switch-off).

The energy absorption capacity is calculated either via the measured resistance using known relationships or relationships to be determined (see FIG. 5), e.g. using statistics or previous measurement, or by determining the measurement duration, charging current and, advantageously, information about the voltage. The efficiency is calculated as the ratio of the amount of charge absorbed and released by the electrical energy storage device. Parasitic influences are taken into account when determining the resistance. The efficiency is determined on site or partially on site.

If a charging device does not allow the implementation of the method disclosed herein, an adapter can be connected between the charging device and the electrical energy storage device, which implements the method.

Further advantageous embodiments can be found in the sub-claims and the description.

### General Advantages

This method makes it possible to objectively compare different electrical energy storage systems. All necessary data is recorded outside the vehicle containing the energy storage system.

The partial or complete local calculation of performance enables the user to have the results available quickly without the need for a time-consuming determination of the load content or a time-consuming and resource-intensive transfer of individual or all data to a cloud.

In addition, the fact that, in contrast to conventional methods, a time-variable current increase or current drop is used within the method to determine the performance, in particular the resistance of the vehicle energy storage system, means that the time-consuming (full) charging and/or (discharge) charging, in particular complete (i.e. charging strokes>90%) or almost complete (i.e. charging strokes>50%), of the energy storage system can be dispensed with.

This procedure makes it possible to use existing charging infrastructure. This saves resources that would otherwise be required to renew the charging infrastructure.

The fact that the charging device is directly coupled to the vehicle energy storage system and/or the intermediate circuit, so that data from the vehicle energy storage system is accessed exclusively or at least primarily, enables battery diagnostics for independent third parties who are not vehicle or battery manufacturers, making it possible to independently assess the state of charge of a vehicle energy storage system and opening up new areas of business for both research and the private sector.

### DESCRIPTION OF THE INVENTION

The method according to the invention describes the determination of the performance of electric vehicle energy storage systems.

For the purposes of the invention, an electric vehicle energy storage system comprises at least one energy-storing element which is suitable for absorbing electrical energy and releasing it again when required. The energy storage device can also be referred to as a secondary battery, accumulator or battery. The process of absorbing electrical energy is referred to as charging. This takes place with a current and a voltage. The process of discharging the electrical energy from the energy-storing element is referred to as discharging or discharging. In general, such elements are referred to as accumulators or secondary batteries, which store electrical energy on an electrochemical basis. In the context of the invention, however, energy-storing elements also include batteries (primary batteries) which cannot be recharged. For the purposes of the invention, energy-storing element, accumulator and battery can be used synonymously. For the purposes of the invention, secondary battery includes lead accumulators, nickel-metal hydride accumulators, lithium-ion accumulators and nickel-cadmium accumulators. The accumulator cells can be connected in series and/or in parallel.

Vehicles within the meaning of the invention include, in particular, automobiles, electric scooters, e-bikes, hoverboards, Segways, ships, boats and gliders. Also included are household appliances powered by accumulators or energy storage devices (e.g. vacuum cleaning robots) or model construction devices (e.g. drones, model aircraft). Since, according to the invention, detailed information from the vehicle can be dispensed with in order to determine the performance of the electric vehicle energy storage system, but only direct access to the energy storage system is required, the energy-storing element or the vehicle energy storage system can advantageously be installed in a vehicle during the method for determining its performance, or be present separately from it.

Preferably, the vehicle energy storage system is integrated into a vehicle while the method for determining its performance is being carried out. This advantageously saves unnecessary work steps to remove the vehicle energy storage system from the vehicle.

The term energy storage also includes stationary energy storage devices, i.e. devices in which accumulators are installed.

In particular, the method according to the invention is intended to allow the remaining capacity of the energy storage device to be determined. For the purposes of the invention, the performance of an electrical energy storage device is understood to mean that the energy-storing element is capable of fulfilling a task intended for it. Such a task includes, for example, the provision of electrical energy in order to convert it either into kinetic energy (e.g. for the operation of an electric motor) and/or into thermal energy (e.g. for the operation of a heating system). Furthermore, the electrical energy cannot be converted into another form of energy, for example if an electrical unit (e.g. sensors, computer) is to be operated. The performance can be referred to as State of Health (SoH). According to the invention, the performance can also be an umbrella term for variables that are yet to be defined. These include, for example, the resistance, the capacitance, or calculations from these or other measured values and/or estimated values. The performance can, for example, be specified as a number. For example, the performance can be indicated according to a traffic light system (e.g. green, yellow, red). For example, the performance can be indicated as a rating (e.g. A, AA, AAA, B, BB, BBB). Irrespective of how the performance is calculated, this should, for example, enable the vehicle owner to make a simple comparison with the performance of other vehicles.

The capacity of the energy storage device can be estimated by determining a first voltage of the energy storage device and/or the intermediate circuit, loading a certain-measured-charge quantity, which is not sufficient to completely fill the energy storage device, into the energy storage device and/or the intermediate circuit, and then determining a second voltage, and then inferring the capacity from the comparison between the difference between the first and second voltage with an expected difference, whereby the expected difference is known from the determined, known charge quantity and previously known information (e.g. stored in lookup tables or a cloud) of the energy storage device or energy storage devices comparable to the energy storage device. information (e.g. stored in lookup tables or a cloud) of the energy storage device or energy storage devices comparable to the energy storage device. Charging leads to a change in voltage. If the actual voltage change is compared with an expected one (e.g. from cloud statistics), it is possible to draw conclusions about the charge absorption capacity.

To determine the performance, the method according to the invention comprises a charging device, which can be detachably connected/installed to the vehicle or permanently connected to the vehicle. Preferably, the charging device is directly and detachably connected to the energy storage device.

A charging device is understood to be an element that supplies or absorbs an amount of electrical energy to the energy-storing element. In particular, a charging device is advantageously located outside the vehicle and, at least during a charging or discharging process, is connected to an energy source, for example an external supply network or another energy storage unit whose energy supply capacity allows a significant charging stroke. What constitutes a significant charging stroke is defined in relation to the total capacity of the energy storage unit and/or to the usual consumption of a vehicle operated with the vehicle energy storage unit. An exemplary charging device can easily charge the energy storage element by at least 10%, or even more, for example 50%, up to 100%. For example, this happens in a few hours, or in less than an hour. A charging device also includes a device that allows additional functions, for example for recording/detecting various parameters. In addition to a charging cable and/or several power channels for supplying the energy storage unit with electrical energy, the charging device and the energy storage unit can also be connected to each other via a data transmission cable, for example a CAN bus (Controller Area Network). However, pure diagnostic devices are not charging devices, as the currents flowing here are generally negligible. Achievable currents are negligible in particular if a charging stroke of 10% would take longer than 1 hour.

The amount of energy emitted can, for example, be controlled by an information technology unit (e.g. computer, electronic circuit).

The charging device comprises at least two power channels. A power channel is understood to be an element that leads from an electrical pole of the charging device to an electrical pole of the energy-storing element, whereby the transported electrical energy is transported through the poles. The voltage between the power channels can be measured with a voltmeter. The current can be measured using an ammeter, for example, which is connected in series with the internal resistance of the energy-storing element. Alternatively, the current can be determined by measuring the voltage across a (known) resistor. A power channel comprises, for example, a charging cable or a plug. A power channel can also comprise a BUS (communication bus/data transmission bus) as a communication interface. A BUS is understood to be a system which, in addition to current-carrying elements that charge a battery, for example, comprises conductor paths that are used for information technology communication, i.e. the transmission of data in electronic form. For example, a USB cable represents a BUS. According to the invention, data transmission standards include a Profibus, USB, OCPP (open charge point protocol).

The current and/or voltage values can be measured at the charging device, which can be located inside or preferably outside the vehicle. A position inside the vehicle is understood to be any position of the charging device that results in the local position of the charging device following that of the vehicle. A position outside the vehicle is understood to be when this is not the case.

In a particularly advantageous embodiment, the charging device can comprise a direct current charging device (DC charging device), which emits or receives a direct current in order to charge the energy-storing element. In this case, a circuit device can be provided which is set up to allow efficient galvanic isolation of a number N of specific energy storage devices from each other and at the same time a coupling with the charging device.

In an alternative embodiment, the charging device can comprise an alternating current charging device (AC charging device), which emits an alternating current to charge the energy-storing element. An AC-DC converter (rectifier) can be provided here. Instead of a single rectifier, which is designed as an AC-DC converter, for example, several rectifiers or AC-DC converters can also be connected in parallel. This allows, for example, a number N of energy storage devices to be advantageously coupled with the charging device. In this case, a switching device can be provided which is set up to allow efficient galvanic isolation of a number N of energy storage devices both from the AC mains and from each other and at the same time coupling with the charging device.

In addition, for a DC charging device and/or an AC charging device, a control device can be provided for controlling the switching device, which is set up to control the coupling of N specific energy storage devices with the charging device. The control device thus allows efficient switching of the switching device for exchanging the number N of energy storage devices with the charging device and thus error-free and uninterrupted charging of the vehicle energy storage devices and determination of the charging data of the vehicle energy storage device by the charging device.

In a further embodiment, the charging device comprises an element which is set up to charge and/or discharge an energy storage device or an energy-storing element.

For example, a charging device for discharging an energy storage device is set up so that an energy storage device or energy-storing element connected to the charging device is to be discharged in order to advantageously reduce the electrical energy it contains, so that the energy storage device or energy-storing element can be removed from a vehicle, for example, and the risk of the energy storage device or energy-storing element exploding is prevented.

For example, the charging device is set up to charge an energy storage device so that an energy storage device or connected energy storage element connected to the charger can be charged. The charging process can be provided via the following four charging systems:
1. Chargers with stabilized output voltage,
2. Pulse chargers,
3. Voltage-stabilizing and current-limiting chargers,
4. AC chargers.

The determination of the performance by means of the method according to the invention comprises the direct or preferably the indirect detection of the resistance of the energy-storing element, i.e. here in particular the consideration and/or removal of “parasitic” influences from other, co-measured components of the intermediate circuit or from connecting elements. For the purposes of the invention, a resistor is understood to be an electrical resistance and/or impedance. This is a measure of the electrical voltage (volts) required to allow a certain electrical current (amperes) to flow through an electrical conductor (e.g. cable, accumulator). An electrical resistance is an ohmic effective resistance if its value is independent of the electrical voltage and the strength of the electrical current and other parameters (e.g. frequency). In the case of inductive elements (e.g. coil) or capacitive elements (e.g. capacitor, accumulator), the resistance changes depending on the frequency and an impedance is added to the ohmic part of the resistance. The total resistance is made up of the ohmic effective resistance and the impedance and is also referred to as impedance. The impedance can be calculated from the behavior of the current and the voltage and is used here synonymously with resistance. The resistance of an energy-storing unit such as an accumulator is related to its capacity. With increasing age or charging/discharging cycles, the resistance of the accumulator increases and its performance decreases. Consequently, by determining the resistance at intervals over time, it is possible to draw conclusions about the capacity or to determine the capacity approximately, particularly in comparison over time and/or particularly advantageously in comparison with other energy storage units

In one embodiment, the charging device is detachably connected to the vehicle. A detachable connection within the meaning of the invention comprises a form-fit, force-fit or material-fit connection or a combination of at least one of these, which is suitable for reversibly attaching the charging device to the vehicle.

In one embodiment of the invention, the performance of the energy storage element is determined without influencing the current flow between the charging device and the energy storage device. Thus, only the measured variables (i.e. at least one current and one voltage) are determined and used, which are determined between a control device of the energy storage device and the charging station, or directly by a user. The person skilled in the art regularly refers to this as a “negotiation”, whereby the charging station is informed of the charging requirement, and possibly also the discharging requirement, in a suitable manner, and this sets the current or power profile accordingly, possibly taking limit values into account. In one embodiment of the invention, the resistance, and thus in further steps the performance, of the energy-storing element is determined indirectly via a calculation or approximation, in that the current flow emitted by the charging device is set such that a variable current increase or current drop (referred to synonymously below as current increase) per unit of time is achieved. A predetermined current increase per unit of time preferably comprises between 0.1 and 10.0 A per second, particularly preferably between 0.1 and 1.0 A per second and most preferably between 0.3 and 0.8 A per second. The current increase can be specified by an information technology unit, whereby the information technology unit can influence the charging time and/or the charging voltage and/or the charging current by varying parameters.

In the present invention, it has proven to be particularly advantageous that a charging current is applied to the energy storage device as a positively or negatively poled charging or discharging current in pulses (i.e. variable current increase and current decrease, followed by a holding time, followed by a current decrease or current increase).

The holding time of a charging pulse can, for example, be between a 1000th and a maximum of 600 seconds, preferably in the range between a 10th and a maximum of 60 seconds.

To determine the performance and, in particular, to determine parasitic components and/or influences that are not attributable to the energy storage device, it can be advantageous to set several pulses of different holding times in different time sequences (“waiting time”) and with different current rise or fall rates. It may be advantageous to set the aforementioned times and/or current levels depending on the performance of the energy storage device and/or measured values in the charging station, in particular the voltage. It may be advantageous to repeat the described procedure several times in the same or adapted form. Current and voltage must always be measured.

The current intensity of the discharging or charging pulse can be varied in a targeted manner during the process for determining the performance of the energy storage device and can take place in smaller or larger amplitudes depending on the estimated state of charge of the energy storage device, the estimated condition of the energy storage device or also depending on the estimated state of the energy storage device and also possibly in shorter current times in order to increase the precision of the determination process, for example on the basis of stored reference measurements.

In a preferred embodiment, a resistance of the energy storage device and/or the intermediate circuit is therefore determined by means of a time-varying current. This can be variable during a charging or discharging pulse and is influenced by all components connected to the charging station (which are also counted as parasitic effects). The profile of the time-varying current can be variable in pulses, whereby the pauses between the pulses can be of the same length or of different lengths. The pulses can be superimposed on an underlying profile. The design of the current profile is advantageously selected in such a way that parasitic influences can be isolated and, in particular, properties of the energy storage device come to the fore.

In addition, steep switching edges can be achieved so that the switching power loss is very low.

Preferably, the first current signal is made up of identical signals whose wave-shaped (in particular sinusoidal) or rectangular or other characteristics are transmitted with a time delay. This allows the state of charge of the energy storage device, the condition of the energy storage device or the state of the energy storage device to be estimated. The comparison can be made, for example, by comparing the data obtained with reference values.

Furthermore, the control of the application of a pulsed charging or discharging current to the energy storage device can be carried out by a computer or a processor of a control unit.

Consequently, a data processing system is also proposed comprising a processor adapted/configured to perform the method or part of the steps of the proposed method.

An information technology unit is an entity that is capable of processing and/or storing electronic data and/or forwarding it and/or displaying it optically or visually. For example, a charging device can be an information technology unit. Such an entity also includes a peripheral device (adapter), provided that it is capable of performing at least one of the steps described.

In the context of the invention, energy absorption capacity refers to the ability of the energy storage element to absorb or release a certain amount of electrical energy and to store it. The energy absorption capacity is related to the charge absorption capacity, i.e. the ability of a storage device to absorb or release a certain amount of charge. The amount of charge that an accumulator or battery can store can be specified in ampere hours (Ah) and the maximum amount of charge that can be stored is also referred to as capacity (nominal capacity). An ampere hour is defined as the amount of charge that flows through a conductor within one hour if the electrical current is a constant 1 A.

The energy absorption capacity can be determined via the ratio of measurement duration and average current level. For example, it is possible to determine the amount of current (current level) that has flowed into the accumulator up to its maximum charge during the period (measurement duration).

As the charge content changes, the voltage of the energy storage device changes in a characteristic manner, so that information about the voltage and, in particular, the change in voltage over the change in charge quantity, the energy storage device, the condition and environmental information (e.g. temperature, parasitic effects) of the energy storage device, as well as known or to-be-determined correlations between the aforementioned variables on the maximum energy absorption capacity and the change over time and/or the comparison with other energy storage devices becomes possible via the presence of the amount of charge fed in or absorbed. Among other things, it is advantageous to have open circuit voltage (“OCV”) characteristics of the available energy storage devices, which can either be pre-determined and stored locally or in a cloud, or result over time from the consideration of many measurements from which statistics can be formed.

Consequently, the charge quantity/charge content of the accumulator can be determined by multiplying the average charging current by the charging time.

For the purposes of the invention, efficiency is understood to be the ratio/quotient of the electrical power absorbed by the energy-storing element during charging and the electrical power delivered during discharging. If the quotient is formed in such a way that the output power is in the numerator, the efficiency of a loss-free accumulator is ideally 1 if the output power corresponds to the absorbed charging power. With increasing age, as well as charging and discharging cycles, the internal resistance of the accumulator increases, which means that part of the electrical energy absorbed is lost as heat. As a result, the efficiency decreases. The ratio of the energy that can be drawn from the battery to the energy required for charging is also referred to as the charging efficiency.

Preferably, parasitic influences are eliminated during the process of determining the performance of the energy storage device.

In the context of the invention, parasitic influences (also: parasitic resistances or parasitic impedances or parasitic ambient conditions) include physical influences that are not attributable to the energy-storing element but, for example, to those in the electrical supply path of a vehicle, e.g. the intermediate circuit or components thereof, as well as contact resistances, plugs, connecting elements, active and passive components, cables and lines. For example, the internal resistance of the accumulator would not be regarded as a parasitic influence, but, for example, line resistances of the power channels, impedances occurring outside the accumulator in the circuit, connector resistances or mutual inductions of spatially adjacent circuits. Those skilled in the art know which influences are covered by parasitic influences and which are covered by the so-called intermediate circuits.

Environmental conditions that have an influence on the resistances and/or the energy absorption capacity, such as the temperature or the temperature distribution within the energy storage device, or the electrical, electrochemical, chemical or thermal equilibrium state, or the degree to which this is reached, are also regarded as parasitic.

For example, information about parasitic impedances in the electrical supply path of a vehicle can be determined by connecting the charger via two current-carrying power channels (connections) to one pole each of an intermediate circuit to which the energy storage device is connected. The skilled person is familiar with methods for obtaining information about impedances from known impedances of the charger and the voltage response of the test object to a suitable, dynamic and/or transient current excitation. In one embodiment, a first voltage drop can be determined at the two terminals in a high-impedance state of the charger, then a second voltage drop can be determined at the two terminals in a low-impedance state of the charger at a defined current flow and then the parasitic resistance can be determined from the first voltage drop, the second voltage drop and the current. In an alternative embodiment, a first voltage drop can also first be determined at the two connections in a low-resistance state of the charger and then a second voltage drop can be determined in a high-resistance state of the charger.

For example, information on parasitic impedances, and therefore on the impedance and thus—as described—the performance of the energy storage device, can also be determined or estimated by investigating the behavior of the voltage at/in the charging station and/or at the intermediate circuit and/or between the power channels with regard to the diffusion- or intercalation-related impedance behavior, in particular relaxation behavior. It is known that typical energy storage devices, in particular Li-ion accumulators, are based on the diffusion or intercalation of charge carriers in an electrode. These processes are manifested by a characteristic behavior of the voltage in response to current flow, which few other known electrical components exhibit. The existence of this phenomenon was already described by Emil Warburg in 1899 Since it can be assumed in typical vehicle topologies that only the energy storage unit exhibits this behavior (and not an electric motor on the DC link, for example), the properties of the energy storage unit—and only the energy storage unit—can be inferred from a search, detection and evaluation of these phases in isolation, even if the measured voltage and/or the measured current represent the overall system, i.e. also include the influences of other components, such as parasitic effects.

Advantageously, information can be determined here from the change in voltage over time (“relaxation”) after (almost) complete termination of current flows and/or after an abrupt change in current strength in or out of the energy store.

The current flow in the low-resistance state can be generated in various ways. For example, a test current can be fed into the charger. According to another variant, a load assigned to the charger can be switched on to generate the current flow. In the latter case, all other electrical consumers of the vehicle can be in the idle state when the corresponding voltage drop is determined.

The determination of the performance by means of the method according to the invention can either be approximated on site (local precalculation) and/or calculated decentrally within a cloud-based information technology system. An on-site position is understood to be a position in the immediate vicinity of the vehicle, preferably within a radius of 50 meters, particularly preferably within a radius of 20 meters and most particularly preferably within a radius of 5 meters. Furthermore, a local position is understood to be a position that is located in the same building as the vehicle.

Advantageously, an approximation on site, for example via a microcontroller, enables the performance of the battery to be determined quickly even if there is no internet connection. In a further embodiment, a more precise calculation can be carried out in a cloud-based information technology system (cloud), which requires an internet connection. The communication path between the device for determining the performance/the information technology unit and the cloud can include a cable connection (e.g. Ethernet cable connection) as well as a wireless connection (e.g. LTE, 4G, 5G) or a connection via WLAN.

In an alternative embodiment, access to the cloud by one or more information technology units enables the inclusion of (stored) data on one or more than one type of accumulator installed in one or more than one vehicle. The stored data can also be stored in another IT unit (e.g. smartphone, notebook, hard disk, USB stick).

According to the invention, a decentralized cloud-based information technology system (cloud) comprises such a system which receives, processes, stores, transmits or sends determined measured values (e.g. voltage, current, temperature, humidity) by means of at least one information technology unit, or a combination of at least one of these. For the purposes of the invention, measured values comprise physical quantities that can be derived either directly or indirectly from the SI units. Measured values include, for example, temperature, time, distance (e.g. mileage in km), amperage, voltage, humidity, acceleration, speed. According to the invention, physical quantities can also be estimated, whereby certain physical quantities are used to estimate another physical quantity. For example, with the aid of a thermometer, for example a contactless thermometer, particularly advantageously an infrared thermometer, which is arranged underneath a vehicle located in the charging station, at least one, advantageously several spatially distributed, temperatures of the housing of the energy storage device can be determined. Advantageously, this makes it possible to estimate the temperature distribution of the energy storage unit without having to access the vehicle's internal systems, which is not possible for a third party. Advantageously, the thermal, electrochemical, chemical and/or thermodynamic equilibrium of the energy storage system can thus be determined.

Measured values can be determined directly or indirectly on at least one vehicle and/or accumulator and/or charging device and/or other element (e.g. adapter). The measured values are determined at intervals. A period of measurement includes, for example, the usage time of the battery. A time period is also understood to be the time difference between an older and a more recent measurement. In one embodiment, a measurement is carried out at a point in time, whereby the measured values obtained are stored in order to make them available for a later measurement, for example.

The advantage of recording various measured values is that it enables a differentiated determination of the performance of the energy-storing element and a forecast of the expected development of performance.

In one embodiment of the invention, the ambient temperature and/or surface temperature of the vehicle and/or energy-storing element can be determined in order to allow conclusions to be drawn about the temperature or equilibrium state of the energy-storing element. In particular, the core temperature of the energy-storing element can also be determined-Furthermore, the surface temperature of the vehicle floor can also be determined. By determining surface temperatures or ambient values, parasitic influences that have an influence on the resistance measurement can be advantageously calculated or estimated.

In one embodiment, an information technology unit can adjust the strength of the charging current and/or the charging voltage depending on one or more than one measured value.

According to the invention, the idle time is understood to be the period in which the vehicle is not moved, whereas the driving time describes the period in which the vehicle is moved, while the operating time describes the period in which energy is taken or absorbed from the energy storage device. This is to be distinguished from the running time, which describes the period in which the battery is discharged without the vehicle being moved. Advantageously, the determination of these measured values/times allows further statements to be made about the expected performance of the energy-storing element, in that these measured values individually or combined with other measured values allow an approximation or calculation of the performance of an energy-storing element. Advantageously, the determination of the standstill time can be used to estimate how far the energy storage device is from its thermal, chemical, electrochemical and/or thermodynamic equilibrium, which has an influence on the resistance measurement. In one embodiment, the measured values are collected at periodic intervals, whereby an information technology unit can determine the intervals.

In one embodiment, the cloud comprises stored data (lookup tables) on the specifications of the different accumulators. A lookup table includes data relating to the charging processes as well as reference data from the battery manufacturers. The data can be obtained from the manufacturers, who publish the corresponding key figures (e.g. nominal voltage, capacity). In an alternative embodiment, the key figures for more than one vehicle and/or more than one energy-storing unit are stored in the cloud. In a particularly preferred embodiment, the data stored in the cloud is used to generate statistics on which the assessment of performance is based. In a further development, the statistics initially comprise stored data on the energy-storing element, for example data from the manufacturer, whereby the statistics are expanded to include collected data in order to better assess the performance.

In a preferred embodiment, at least one information technology unit compares the data stored in the cloud with the measured values determined. In a particularly preferred embodiment, the data is transferred from the cloud to one or more mobile telecommunications devices (e.g. smartphone, tablet, notebook), which enables the data to be displayed graphically. In a further embodiment, the measured values determined are transmitted to the cloud and compared there with the measured values of other accumulators.

In a particularly preferred embodiment, the information on each individual battery that is charged via a charging device that is directly or indirectly connected to the cloud is stored in the cloud. This makes it advantageous for an algorithm and/or preferably an artificial intelligence (AI) that has access to the cloud to decide which battery is charged with which charging voltages and/or charging currents and/or charging times. The AI can therefore determine optimum charging curves. The advantage of this is that the AI can use modeling to determine the parameters that result in optimum battery performance based on the measured values that develop differently over time for each battery. In doing so, the AI must ensure that it only varies the parameters within a limited range so that no customer has to accept an intolerable negative impact on performance caused by the AI. This has the advantage of improving the performance of the energy-storing element.

In a further embodiment, not only are the measured values of the accumulators stored in the cloud and/or processed by an AI, but other measured values relating to the vehicle, such as speed and downtimes, are also determined and processed. The measured values preferably come from more than one, particularly preferably more than a thousand and very particularly preferably more than a million vehicles and/or energy-storing elements.

Preferably, the measured values are collected by a measuring device that is installed with the vehicle and/or the energy-storing element and/or an adapter and/or the charging device and is used to determine physical variables (e.g. temperature, voltage, current, acceleration, speed). For example, at least one heat-dependent resistor (e.g. NTC resistor, PTC resistor) or a contactless temperature measuring device (e.g. an infrared thermometer) can serve as a measuring device, which is located on and/or next to and/or inside the energy-storing element and transmits information to the measuring device via an electrical circuit. For the purposes of the invention, a measuring device is not to be understood as a single element. Instead, the measuring device comprises all elements that detect a physical quantity, whereby the measured values can be detected simultaneously and/or not simultaneously.

In one embodiment, there may be a mat underneath the vehicle in which temperature sensors, e.g. contactless sensors, are arranged in order to allow conclusions to be drawn about at least one representative temperature, e.g. the average internal temperature or the temperature distribution of the energy-storing element, via the measurement and with the aid of the statistics.

In a preferred embodiment, the method according to the invention is implemented with an adapter, which is an embodiment of an information technology unit, in which one or more measuring devices are integrated. Advantageously, the adapter has control over the current delivered by the charging unit. This is particularly advantageous if the charging unit itself cannot establish contact with a cloud, but the adapter can. The adapter can then access the stored data and regulate the charging time and/or the charging voltage and/or the charging current depending on this.

One embodiment of the method according to the invention for determining the performance of electric vehicle energy storage systems comprises determining the state of charge (SoC) of the energy storage element (e.g. accumulator) to determine the performance. The SoC is a characteristic value for the state of charge of accumulators. The SoC value indicates the amount of charge still available in a rechargeable battery in relation to the nominal value. The state of charge is given as a percentage of the fully charged state. For example, an SoC of 30% means that the battery still has a residual charge of 30% in relation to the original full charge of 100%. Knowing or estimating the SoC is a good way of determining the energy storage capacity.

In a further embodiment, the information about the state of charge can be transmitted by an additional communication interface between the vehicle and the charging station, whereby the additional communication interface can comprise an adapter. For the purposes of the invention, a communication interface also comprises the charging cable or the vehicle driver, who makes a manual input, i.e. a manual transmission of data to a charging device, for example.

In an alternative embodiment, the adapter establishes a connection to the cloud in order to exchange data with it or to store data in it. In a preferred embodiment, the adapter establishes a connection to one or more mobile telecommunications devices (e.g. smartphone, tablet, notebook) and/or a technical unit that processes information technology signals in order to exchange data. An additional communication interface advantageously means that the charging device does not have to be coordinated with the battery management system (BMS). Instead, the additional communication interface ensures correct data exchange between the BMS and the charging device and/or at least one other IT unit.

In a particularly preferred embodiment, the measured values determined for the energy-storing unit include, for example, physical variables such as voltage, current (in particular current peaks), temperature, temperature fluctuations, humidity and the age of the accumulator. Measured values can also include vehicle movement, in particular acceleration. Advantageously, a more precise calculation of the performance of the energy-storing element can be achieved with the aid of a combination of individual measured values.

The age of the energy-storing element is understood to be the period from its first use to the current time of use. The age of an accumulator allows a more differentiated determination of the performance of the energy-storing element.

In an alternative embodiment, parts of the measured values can be read out by a diagnostic interface, a head-up display or a dashboard or a combination thereof. The readout can be carried out by an information technology unit. Optionally, the readout can be carried out in such a way that the vehicle driver manually transmits the measured values to an information technology unit.

In one embodiment, the vehicle and/or the energy-storing element can be uniquely identified by means of an identification method. Various possibilities are known to the skilled person from the state of the art for providing objects, in particular electronic systems (e.g. the vehicle, the battery) and information technology systems, with an identifier that can be determined and processed by an information technology unit (e.g. data stored on an RFID chip). In a preferred embodiment, the identifier is transmitted to the adapter and/or the charging device and/or the cloud and/or the mobile communication device. In a particularly preferred embodiment, the vehicle, and/or the energy-storing element, and/or the adapter, and/or the charging device and/or the cloud and/or the mobile communication device comprise an identifier. For the purposes of the invention, an identifier comprises a numerical value such as 283163849. The identifier may be visibly applied to the unit that it identifies and/or stored in information technology. An identifier further comprises a vehicle identification number, a MAC address, or the license plate number of the vehicle.

In an embodiment, the vehicle and/or the energy-storing element is identified by a user input on a display. The display transmits the information entered to an information technology unit for processing. In a preferred embodiment, the charging device comprises a display. The display can also be part of the vehicle, the mobile communication device or the adapter. Alternatively, identification can take place via a charging card that is inserted into the charging device.

In an alternative embodiment, the vehicle and/or the energy-storing element and/or the vehicle driver/user are identified via a camera. For example, the identifier can be designed in such a way that the vehicle license plate number or the facial image of the vehicle driver is stored in an information technology system (e.g. the cloud), whereby the data on the vehicle and/or the energy storage unit is stored at the same time. Advantageously, the vehicle owner therefore does not have to make any manual entries. Alternative embodiments use, for example, an iris scan and/or a fingerprint of the vehicle driver.

In a further embodiment, the vehicle and/or the energy-storing element is identified using Plug and Charge or Autocharge or OCCP. Charging processes are started or ended simply by connecting or disconnecting the charging cable in charging devices that use these methods. This eliminates the need to use a charging card for identification. Both are standardized charging methods that offer an additional communication interface and at least one identification option.

In one embodiment, the energy absorption capacity is determined to determine the performance, i.e. the time span in which the energy-storing element reaches the maximum charge content. This is relevant for the determination because the ability of an accumulator to store a defined amount of charge in a specified time deteriorates with increasing age. Assume that a new and an older accumulator of the same model are charged with the same charging voltage, whereby the current is adjusted according to the resistance. For example, while the new accumulator reaches a charge capacity of 100 kWh within 10 hours, an old accumulator reaches a charge capacity of 90 kWh within 13 hours. Its performance is therefore poorer. Therefore, recording this period of time can be used to determine the performance.

### Design Examples

The present invention is explained in more detail with reference to the following figures and embodiments, without limiting the invention to these.

FIG. 1 In a first embodiment example, the method according to the invention comprises an electrically powered vehicle EV (electric vehicle) 2 with an electrical energy storage device 1, a charging device 3, which is detachably connected to the electrical energy storage device 1 via a charging cable 4. A device for determining the performance is integrated into the charging device 3 and communicates with the electric energy storage device 1 via an additional communication bus, which is combined with the charging cable 4, and with a cloud server 5 via a second communication path.

In this embodiment, the energy storage device is formed from a lithium-ion accumulator, wherein the performance of the electrical energy storage device 1 is related to the resistance and the energy absorption capacity of the energy storage device 1 and wherein the performance is abbreviated as SoH (State of Health) and wherein the electrical energy storage device 1 consists of accumulator cells connected in parallel and in series.

In this embodiment, the data transmission bus between the device for determining the performance and the electrical energy storage device 1 is designed as a serial interface and uses the CAN bus transmission standard. The device for determining the performance thereby accesses sensor values of the vehicle and the electrical energy storage device such as charging current, charging voltage, SOC (state of charge) and the cell temperature inside the electrical energy storage device 1, provided these are approved by the manufacturer. In addition, historical data of the electrical energy storage device 1, such as charging cycles and mileage of the vehicle, vehicle downtime, temperature profile of the vehicle floor and the vehicle environment are transmitted to the device to determine the performance.

The data during the charging process, which includes current, voltage, SOC and temperature inside the electrical energy storage device 1, is recorded in real time during the charging process by the device for determining the performance.

A unique identification procedure is used to identify and assign electrical energy storage units 1 and vehicles 2. The identification features are transmitted via the additional communication interface for the identifier. Alternatively, the identification of vehicles and electrical energy storage devices is carried out by user input or by image recognition using a camera or by plug and charge or by autocharge.

The communication path between the device for determining the performance and the cloud server is established via an Ethernet cable connection.

In the present embodiment example, the charging data and historical data of various electrically powered vehicles 2 and electrical energy storage devices are stored on the cloud server in a lookup table. This data is retrieved by the device to determine the performance and is supplemented by the charging data and historical data measured after each charging process.

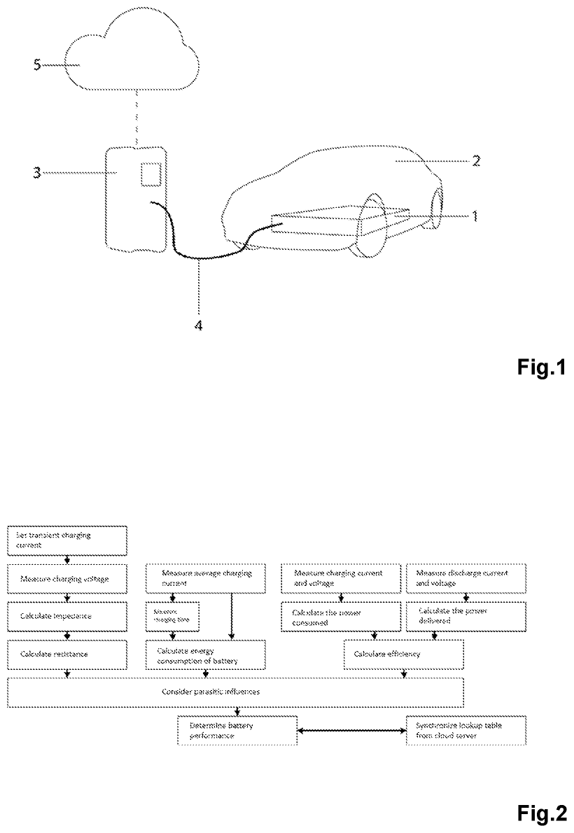

FIG. 2 In the present embodiment example, parasitic influences of the charging device and the electrical energy storage device are taken into account. These parasitic influences include cable resistances and counter-induction, energy consumption by auxiliary consumers and contact resistances.

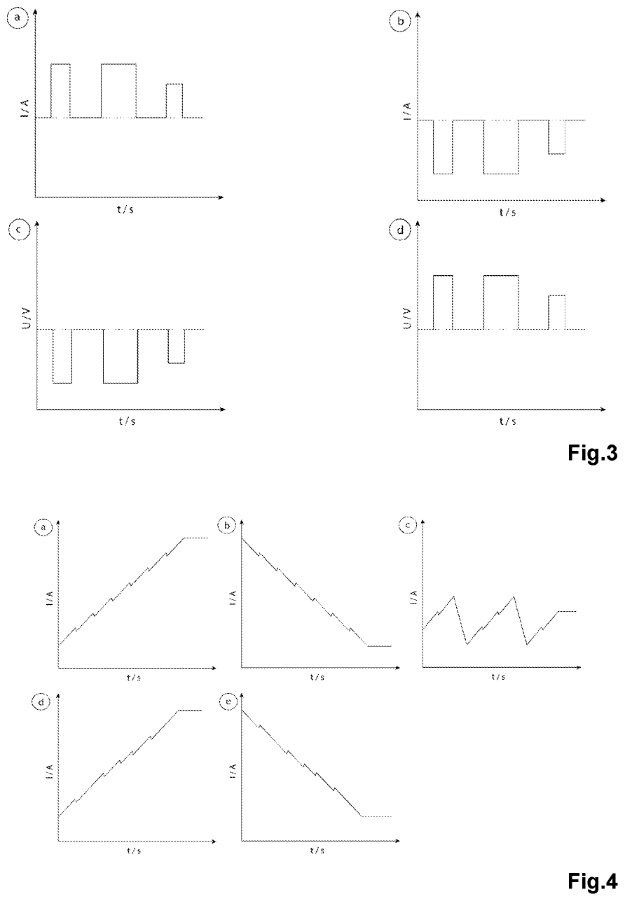

To determine the performance of an energy storage device 1, the charging current is set to pulsed. The pulse width or amplitude of the pulse is set variably (FIG. 3a). When loading the energy storage device, the current is also set with variable pulse width or amplitude (FIG. 3b). Instead of the current, the charging and discharging voltage can also be set variably over time with variable pulse width or amplitude (FIGS. 3c and 3d).

To determine the resistance of the electrical energy storage device 1 during charging, a transient (time-varying) charging current is set by the charging device, as shown in FIG. 4. The charging current in FIG. 4a rises with a predetermined increase and falls with small, regular decreases until it reaches a prescribed current level. The impedance and the resistance of the electrical energy storage device 1 are determined from the voltage response. The corresponding parasitic resistances are then taken into account. Using a measured reference energy storage device, corresponding charge contents are specified for the determined resistances, generally measured values, from which conclusions are drawn about the capacity, as shown in FIG. 5a. The historical reference values result in a spread, which is shown by the dashed lines. The more reference values there are, the more accurate the result. In FIG. 5b, the measured values of another energy storage device are compared with the reference values in order to draw conclusions about its performance.

Alternatively, the average charging current is multiplied by the charging time to determine the charge quantity of the electrical energy storage device. The corresponding parasitic influences are then taken into account. To calculate the efficiency of an electrical energy storage system, the discharge quantity is set in relation to the charge quantity.

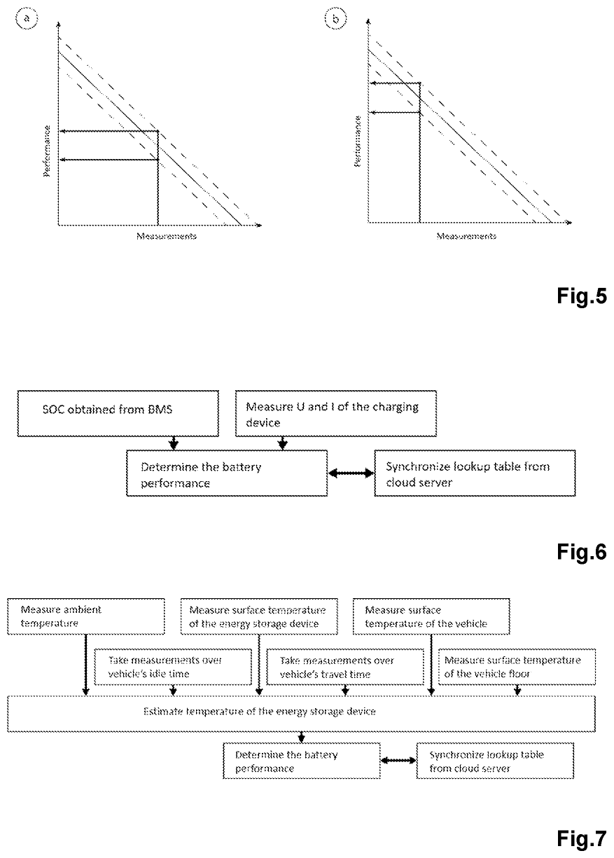

FIG. 6 In a further embodiment example, in addition to the first embodiment example, further measured values are taken into account to determine the performance of electrical energy storage devices 1. A further measured value is the SOC of the electrical energy storage device 1. The SOC is transmitted via a communication interface from the BMS (battery management system) to the device for determining the performance.

Another way to determine the SOC is to measure the charging voltage and charging current, comparing these measured values with reference values of a new electrical reference energy storage system from a lookup table on a cloud server. In addition to the reference values, the lookup table on the cloud server holds historical charging data and identification features of vehicles and electrical energy storage systems.

The maximum current flow of a new electrical reference energy storage system must be 0.25 1/h of the maximum charge content.

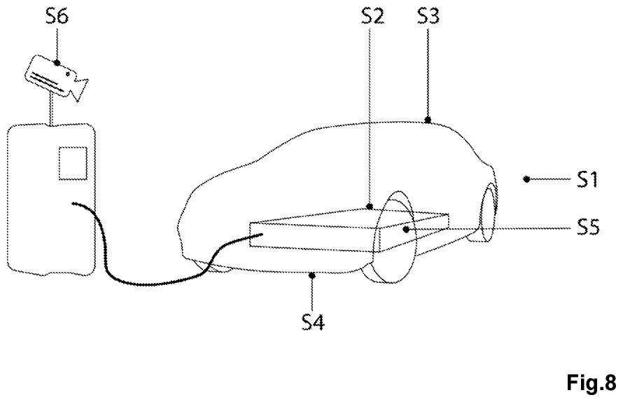

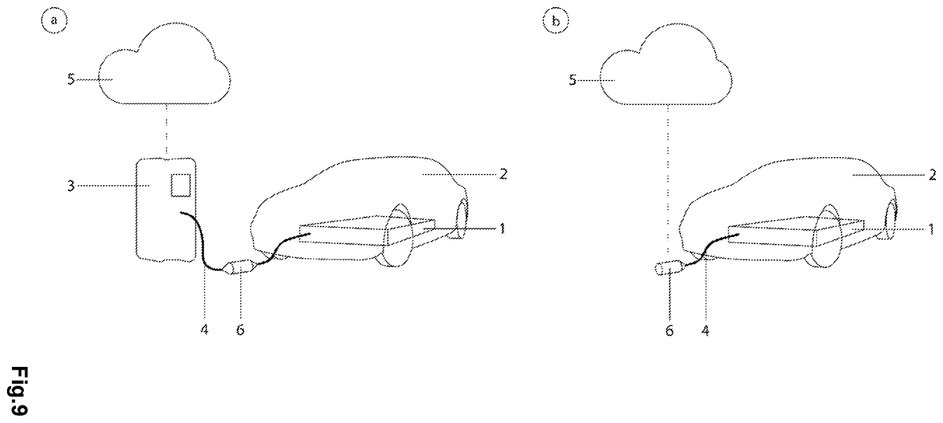

FIG. 7A further embodiment example takes into account further measured values for determining the performance of electrical energy storage devices, wherein one measured value is the temperature of the electrical energy storage device and wherein this temperature is either provided by the SOC (FIG. 8 S5), or in alternative embodiments is estimated on the basis of weather values, such as the temperature, temperature fluctuations and humidity of the vehicle environment (FIG. 8 S1), the surface temperature of the energy storage device (FIG. 8 S2), the vehicle (FIG. 8 S3) or the vehicle floor (FIG. 8 S4). These parameters are recorded over a period of time and the temperature of the electrical energy storage unit is determined from this, whereby this period of time includes the driving time as well as the idle time of the vehicle. These measured values are transmitted to the performance assessment device via a communication interface.

In another embodiment, the age of the electrical energy storage system is used as a further parameter to determine the performance. The mileage of the vehicle with this electrical energy storage unit is also taken into account. For the procedure for assessing the performance of electrical energy storage systems, information on other electrical vehicle energy storage systems is collected.

To identify the vehicle and the energy storage unit inside, the license plate is read by the camera (FIG. 8 S6). To assess the vehicle temperature, the camera (FIG. 8 S6) is additionally or exclusively capable of generating thermal images. The current temperature of the energy storage unit is deduced from the thermal image. In addition, the temperature curve is determined when the vehicle is stationary in front of the charging device.

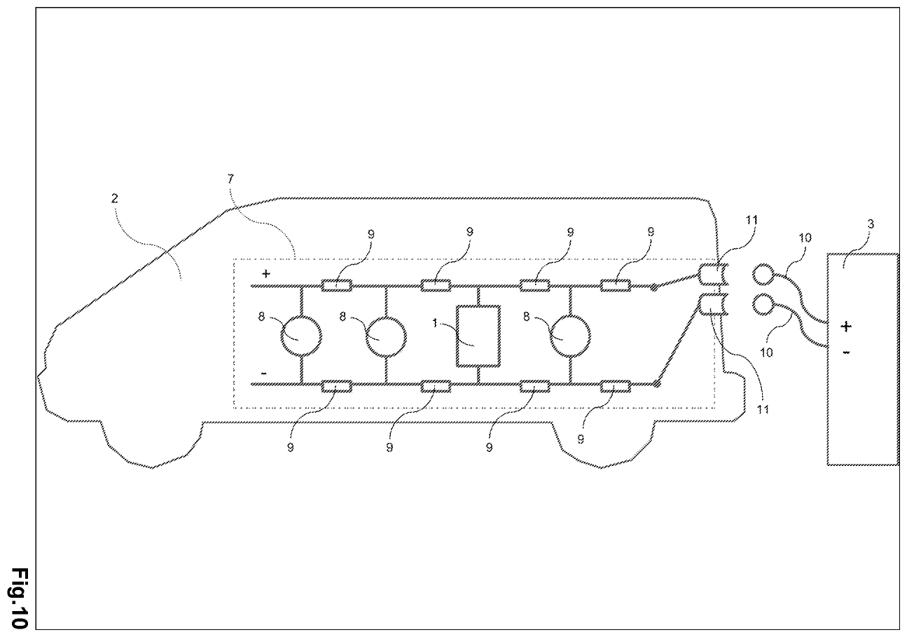

FIG. 9a In the event that existing charging devices 3 do not provide the options for implementing the procedure for assessing the performance of electrical energy storage devices 1, an adapter 6 can alternatively be attached to supplement the charging device 3. This contains all the functions for assessing the performance of electrical energy storage devices 1 and is connected to the charging device via a charging cable 4. In another version, the adapter 6 communicates directly with the cloud server 5 via a wireless internet connection (FIG. 9b).

A typical embodiment of an intermediate circuit (7) of an electrically powered vehicle is shown in FIG. 10. An intermediate circuit (7) is defined here as the set of galvanically coupled components (1, 8, 9), for example auxiliary consumers, power electronics, motors, heating/cooling devices, with their own respective electrical parasitic properties, one of these components corresponding to the vehicle energy storage unit (1), and the intervening parasitic impedances (9), such as transition and cable/line resistances, parasitic capacitances and inductances and stray capacitances and stray inductances, and the connections of the power channels (10) for the electrical power consumption from the charging device. In the embodiment shown, the voltage measured by a measuring device in the charging device between the two power channels (10) corresponds to the voltage between the poles of the intermediate circuit (11), taking into account current or parasitic effects.

The current that can flow here from the charging device in the direction of the intermediate circuit will be divided between the various components according to the parasitic impedance properties of the components. Part of the current will flow into the vehicle energy storage system (1).

By appropriately setting and/or determining the voltage by the charging station (3), which is set in conjunction with the current flow, which is also determined and/or set, as well as predetermined correlations to the nature of the parasitic properties, e.g. through information stored in a cloud, the effect of the parasitic components can be determined or estimated and thus conclusions can be drawn about the electrical properties of the vehicle energy storage system.

### LIST OF REFERENCE SYMBOLS

1 Vehicle energy storage unit
2 Electric vehicle (EV)
3 Charging device
4 Charging cable
5 Cloud server
6 Adapter
S1 Vehicle environment
S2 Surface temperature of the energy storage unit
S3 Surface temperature of the vehicle
S4 Surface temperature of the vehicle floor
S5 State of charge (SOC)
S6 Camera
7 Intermediate circuit
8 Other intermediate components
9 Parasitic impedances
10 Power channels
11 Pole of the intermediate circuit

1-58. (canceled)

59. A method for determining the performance of electric vehicle energy storage units (1) comprising
a) Providing a vehicle energy storage unit (1) connected to an intermediate circuit (7),
b) Providing a charging device (3) that can be detached from the vehicle energy storage unit (1) or from the intermediate circuit (7),
c) Providing at least two current-carrying power channels (10), preferably directly from the charging device (3) to the vehicle energy storage unit (1) or the intermediate circuit (7),
d) Determining at least one current, in particular at least one amperage, of the vehicle energy storage unit (1),
e) Determining at least one voltage of the vehicle energy storage unit (1),
f) Determining at least one resistance of the vehicle energy storage unit (1), and
g) Determining further physical variables as measured values,
whereby a time-variable current increase or current drop is used to determine the performance, in particular the resistance, of the vehicle energy storage unit (1),
whereby the current and voltage are determined outside of the vehicle (2), preferably inside the charging device (3),
wherein influences, in particular parasitic effects, of components (8, 9) other than the energy storage unit (1) connected to the intermediate circuit (7) and/or components between the charging device (3) and the energy storage unit (1) are compensated for to determine the performance of the energy storage unit (1),
whereby at least one external physical variable and already known information about the energy storage unit (1) or already known information about energy storage units comparable to the energy storage unit (1) are used to compensate for those influences.

60. The method according to claim 59, wherein the determining of the performance is carried out via an approximation on site and/or a more precise calculation in a cloud (5), wherein the determining of the performance is carried out, in whole or in part, in particular in a distributed manner
in the charging device (3), in particular its computing units,
in at least one computing unit in the immediate vicinity of the charging device (3), in particular within a radius of 100 m, in particular 50 m, in particular 30 m,
and/or
on one or more, in particular distributed, servers (5), in particular in the context of cloud and/or edge computing.

61. The method according to claim 59, wherein the performance is related to the change in resistance and/or charge absorption capacity in comparison with each other and/or in comparison with a determination of the values at a previous point in time and/or wherein the performance is determined by determining at least the resistance and/or the charge absorption capacity and comparing it with the resistance and/or the charge absorption capacity of known energy storage units which are comparable with the energy storage unit.

62. The method according to claim 59, wherein the state of charge of the energy storage unit is used to determine the performance, in particular wherein the state of charge is transmitted via an additional communication interface between the vehicle and the charging device.

63. The method according to claim 62, wherein via an additional communication interface between the vehicle and the charging device are furthermore transmitted one or more of:
Voltage of the vehicle energy storage unit (1) and/or the intermediate circuit (7)
Voltages of individual parts of the vehicle energy storage unit (1), in particular individual cells and/or modules and/or strings of the energy storage unit
Current levels of individual parts of the vehicle energy storage unit (1), in particular individual cells and/or modules and/or strings of the energy storage unit
Temperatures, in particular average, minimum, maximum or other aggregations of temperatures of the energy storage unit (1)
Ageing parameters of the vehicle energy storage unit (1), in particular capacities, resistances, impedances, age, mileage, state of health (SOH),
and/or nominal sizes of the vehicle energy storage unit (1), in particular the nominal capacity of the vehicle energy storage unit (1) when new.

64. The method according to claim 62, wherein the state of charge is determined from the voltage applied to the energy store (1) or is estimated using stored data and/or wherein the state of charge is determined and/or estimated by using a temporal integration of a current signal and/or a power signal and/or wherein the state of charge is determined and/or estimated using effects of quiescent phases and/or quasi-quiescent phases, in particular relaxed voltages and/or phases of still-progressing relaxation of the voltage and/or wherein the state of charge is determined and/or estimated by using a temporal integration of a current signal and/or a power signal,
before and/or after
the rest phases and/or quasi-rest phases to improve the determination of performance.

65. The method according to claim 59, wherein one or more measured values are used to estimate and/or calculate the performance over a period of time; and/or wherein an artificial intelligence makes an adjustment of the charging current and/or voltage and/or charging time on the basis of measured values and/or stored data.

66. The method according to claim 65, wherein a measured value comprises a representative temperature of the vehicle and/or the energy storage unit, in particular wherein the representative temperature comprises the ambient temperature and/or surface temperature and/or average temperature and/or minimum temperature and/or maximum temperature and/or wherein the measured value comprises the surface temperature of the energy storage unit and/or the vehicle floor.

67. The method according to claim 65, wherein the measured values are transmitted to the charging device via an additional communication interface between the vehicle and the charging device and/or wherein at least one or more of the measured values are used when calculating out influences of other components, in particular parasitic effects, and/or wherein the calculation of parasitic influences is based on the evaluation of relaxation processes and/or relaxation phases in a voltage signal of the energy storage unit and/or the intermediate circuit, in particular for identifying, determining and/or estimating impedance characteristics and/or parameters of the vehicle energy storage unit.

68. The method according to claim 65, wherein a measured value comprises the age of the energy storage unit, the running time and/or the mileage of the vehicle and/or comprises one or more of:
Voltage of the vehicle energy storage unit (1) and/or the intermediate circuit (7)
Voltages of individual parts of the vehicle energy storage unit (1), in particular individual cells and/or modules and/or strings of the energy storage unit
Current levels of individual parts of the vehicle energy storage unit (1), in particular individual cells and/or modules and/or strings of the energy storage unit
Temperatures, in particular average, minimum, maximum or other aggregations of temperatures of the energy storage unit
Ageing parameters of the vehicle energy storage unit (1), in particular capacities, resistances, impedances, age, mileage, state of health (SOH),
and/or nominal sizes of the vehicle energy storage unit (1), in particular the nominal capacity of the vehicle energy storage unit when new.

69. The method according to claim 59, wherein the charging current intensity is adjusted as a function of at least one measured value and/or wherein one or more vehicles and/or their contained energy storage units are uniquely identified using an identification method and/or which can be executed and/or can enable communication between a charging device (3) and an energy storage unit (1) if these are not coordinated with one another.

70. A device set up to effectively provide a user with the determination of a performance according to the method of claim 59, in particular a communicative adapter (6) for arrangement on and/or connection at both ends of the vehicle energy storage unit (1) and the charging device (3), for communication with at least the vehicle energy storage unit (1) and/or intermediate circuit (7) arranged on the vehicle energy storage unit (1), in particular also set up for communication with the charging device (3) for the vehicle energy storage unit (1), in particular furthermore set up for communication with one or more servers and/or computing units, in particular in communication with a computing cloud (5), which device is set up to effectively provide a user with the determination of the performance in particular to make it effectively available for acknowledgement and/or further data processing,
especially if the charging device (3) and the vehicle energy storage unit (1) are not matched to each other.

71. A distributed computer system using the device according to claim 70 arranged to carry out the method for determining the performance of electric vehicle energy storage units (1).

72. A computer program or computer-readable medium comprising computer-executable instructions which, using the device of claim 70, when executed by a computer, cause it to effect the method for determining the performance of the electric vehicle energy storage unit.

73. The method according to claim 59 using a device set up to effectively provide a user with the determination of the performance, in particular a communicative adapter (6) for arrangement on and/or connection at both ends of the vehicle energy storage unit (1) and the charging device (3), for communication with at least the vehicle energy storage unit (1) and/or intermediate circuit (7) arranged on the vehicle energy storage unit (1), in particular also set up for communication with the charging device (3) for the vehicle energy storage unit (1), in particular furthermore set up for communication with one or more servers and/or computing units, in particular in communication with a computing cloud (5), which device is set up to effectively provide the user with the determination of the performance in particular to make it effectively available for acknowledgement and/or further data processing, especially if the charging device (3) and the vehicle energy storage unit (1) are not matched to each other,
to enable communication between the charging device (3) and the energy storage unit (1) when they are not matched.
